(19) United States
(12) Patent Application Publication
(10) Pub. No.: US 2008/0066802 A1
(43) Pub. Date: Mar. 20, 2008

(54) PHOTOVOLTAIC DEVICE CONTAINING NANOPARTICLE SENSITIZED CARBON NANOTUBES

(75) Inventor: Damoder Reddy, Los Gatos, CA (US)

Correspondence Address: MORGAN, LEWIS & BOCKIUS, LLP, ONE MARKET SPEAR STREET TOWER, SAN FRANCISCO, CA, 94105, US

(73) Assignee: SOLEXANT CORP., Sunnyvale, CA (US)

(21) Appl. No.: 11/690,094

(22) Filed: Mar. 22, 2007

Related U.S. Application Data
(60) Provisional application No. 60/785,651, filed on Mar. 23, 2006.

(51) Int. Cl. H01L 31/04; H01L 31/0296; H01L 31/0304; H01L 31/032

(52) U.S. Cl. 136/258; 136/252; 136/260; 136/261; 136/264; 136/265; 977/742; 977/750; 977/762; 977/774

(57) ABSTRACT

This invention relates to photovoltaic devices made with photoactive nanostructures comprising carbon nanotubes and photosensitive nanoparticles.

This application claims the benefit of U.S. Provisional Patent Application Ser. No. 60/785,651, filed on Mar. 23, 2006, under 35 U.S.C. §119(e), which is incorporated herein by reference in its entirety.

### FIELD OF THE INVENTION

The invention relates to the use of carbon nanotubes and photoactive nanoparticles, including nanoparticles of different size and composition, to form photovoltaic devices.

### BACKGROUND OF THE INVENTION

Increasing oil prices have heightened the importance of developing cost effective renewable energy. Significant efforts are underway around the world to develop cost effective solar cells to harvest solar energy. Current solar energy technologies can be broadly categorized as crystalline silicon and thin film technologies. More than 90% of the solar cells are made from silicon—single crystal silicon, polycrystalline silicon or amorphous silicon.

Historically, crystalline silicon (c-Si) has been used as the light-absorbing semiconductor in most solar cells, even though it is a relatively poor absorber of light and requires a considerable thickness (several hundred microns) of material. Nevertheless, it has proved convenient because it yields stable solar cells with good efficiencies (12-20%, half to two-thirds of the theoretical maximum) and uses process technology developed from the knowledge base of the microelectronics industry.

Two types of crystalline silicon are used in the industry. The first is monocrystalline, produced by slicing wafers (approximately 150 mm diameter and 350 microns thick) from a high-purity single crystal boule. The second is multicrystalline silicon, made by sawing a cast block of silicon first into bars and then wafers. The main trend in crystalline silicon cell manufacture is toward multicrystalline technology. For both mono- and multicrystalline Si, a semiconductor p-n junction is formed by diffusing phosphorus (an n-type dopant) into the top surface of the boron doped (p-type) Si wafer. Screen-printed contacts are applied to the front and rear of the cell, with the front contact pattern specially designed to allow maximum light exposure of the Si material with minimum electrical (resistive) losses in the cell.

Silicon solar cells are very expensive. Manufacturing is mature and not amenable for significant cost reduction. Silicon is not an ideal material for use in solar cells as it primarily absorbs in the visible region of the solar spectrum thereby limiting the conversion efficiency.

Second generation solar cell technology is based on thin films. Two main thin film technologies are amorphous silicon and CIGS.

Amorphous silicon (a-Si) was viewed as the “only” thin film PV material in the 1980s. But by the end of that decade, and in the early 1990s, it was dismissed by many observers for its low efficiencies and instability. However, amorphous silicon technology has made good progress toward developing a very sophisticated solution to these problems: multijunction configurations. Now, commercial, multijunction a-Si modules could be in the 7%-9% efficiency range. United Solar Systems Corporation and Kanarka plan have built 25-MW manufacturing facilities and several companies have announced plans to build manufacturing plants in Japan and Germany. BP Solar and United Solar Systems Corporation plan to build 10 MW facilities in the near future.

The key obstacles to a-Si technology are low efficiencies (about 11% stable), light-induced efficiency degradation (which requires more complicated cell designs such as multiple junctions), and process costs (fabrication methods are vacuum-based and fairly slow). All of these issues are important to the potential of manufacturing cost-effective a-Si modules.

Thin film solar cells made from Copper Indium Gallium Diselenide (CIGS) absorbers show promise in achieving high conversion efficiencies of 10-12%. The record high efficiency of CIGS solar cells (19.2% NREL) is by far the highest compared with those achieved by other thin film technologies such as Cadmium Telluride (CdTe) or amorphous Silicon (a-Si).

These record breaking small area devices have been fabricated using vacuum evaporation techniques which are capital intensive and quite costly. It is very challenging to fabricate CIGS films of uniform composition on large area substrates. This limitation also affects the process yield, which are generally quite low. Because of these limitations, implementation of evaporation techniques has not been successful for large-scale, low-cost commercial production of thin film solar cells and modules and is non-competitive with today's crystalline silicon solar modules.

To overcome the limitations of the physical vapor deposition techniques that use expensive vacuum equipment, several companies have been developing high throughput vacuum processes (ex: DayStar, Global Solar) and non-vacuum processes (ex: ISET, Nanosolar) for the fabrication of CIGS solar cells. Using ink technology, very high active materials utilization can be achieved with relatively low capital equipment costs. The combined effect is a low-cost manufacturing process for thin film solar devices. CIGS can be made on flexible substrates making it possible to reduce the weight of solar cells. Cost of CIGS solar cells is expected to be lower than crystalline silicon making them competitive even at lower efficiencies. Two main problems with CIGS solar cells are: (1) there is no clear pathway to higher efficiency and (2) high processing temperatures make it difficult to use high speed roll to roll process and hence they will not be able to achieve significantly lower cost structure.

These are significant problems with the currently available technologies. Crystalline silicon solar cells which have >90% market share today are very expensive. Solar energy with c-silicon solar cells costs about 25 cents per kwh as compared to less than 10 cents per kwh for fossil fuels. In addition, the capital cost of installing solar panels is extremely high limiting its adoption rate. Crystalline solar cell technology is mature and unlikely to improve performance or cost competitiveness in near future. Amorphous silicon thin film technology is amenable to high volume manufacturing that could lead to low cost solar cells. In addition, amorphous and microcrystal silicon solar cells absorb only in the visible region.

Next generation solar cells are required to truly achieve high efficiencies with light weight and low cost. Two potential candidates are (1) polymer solar cells and (2) nanoparticle solar cells. Polymer solar cells have the potential to be low cost due to roll to roll processing at moderate temperatures (<150 C). However, polymers suffer from two main drawbacks: (1) poor efficiencies due to slow charge transport and (2) poor stability- especially to UV radiation. Hence it is unlikely that polymer solar cells will be able to achieve the required performance to become the next generation solar cell. The most promising technology for the next generation solar cell is based on quantum dot nanoparticles.

Several research groups have been conducting experimental studies on quantum dot based solar cells. Most commonly used quantum dots are made of compound semiconductors such as Group II-VI, II-IV and III-V. Some examples of these photosensitive quantum dots are CdSe, CdTe, PbSe, PbS, ZnSe.

Solar cells made from photosensitive nanoparticles as described in the art show very low efficiencies (<5%). Nanoparticles are very efficient in generating electron hole charge pairs when exposed to sunlight. The primary reason for these low efficiencies is charge recombination. To achieve high efficiencies in a solar cell the charges must be separated as soon as possible after they are generated. Charges that recombine do not produce any photocurrent and hence do not contribute towards solar cell efficiency. Charge recombination in nanoparticles is primarily due to two factors: (1) surface states on nanoparticle that facilitate charge recombination, and (2) slow charge transport. In the later case, charge recombination is generally faster compared to the charge transport rate because charges travel slowly through the electron transport and hole transport layers.

Various methods have been reported in the prior art to solve these problems of nanoparticles. Surface treatment techniques have been tried to remove surface states. (See Furis et al, MRS Proceedings, volume 784, 2004) Such techniques show improvement in photoluminescence but do not improve solar conversion efficiency as they do not impact the charge transport properties of hole transport and electron transport layers.

It is known in the art that TiO₂ layers can be used to rapidly transport electrons. Dye-sensitized solar cells use TiO₂ precisely for this reason. Transparent TiO₂ nanotubes have been reported in the literature (Mor et al., Adv. Funct. Mater., 2005, 15, 1291-1296 (2005)). These TiO₂ nanotubes have been used to prepare dye-sensitized solar cells.

Single wall carbon nanotubes (SWCNT) have been used as light absorbing material in solar cells. In addition, nanoparticles such as CdSe and CuInS have been covalently attached to carbon nanotubes. See Landi et al., Mater. Res. Symp. Proc. Vol. 836, 2005, Session L2.8 pages 1-6.

### SUMMARY OF THE INVENTION

The photvoltaic devises include first and second electrodes at least one of which is transparent to solar radiation. A photoactive layer between the first and second electrodes contains photoactive nanostructures comprising carbon nanotubes (CNT) and photosensitive nanoparticles. The nanoparticles are closely associated with the carbon nanotubes and in some embodiments are covalently attached to the CNT. The photoactive layer is in electron conducting communication with the first electrode and in hole conducting communication with the second electrode. In some embodiments the photoactive layer further comprises a conducting polymer.

In other embodiments, the photovoltaic device further includes a hole conducting layer between the first electrode and the photoactive layer that facilitates hole transfer to the first electrode. In a preferred embodiment, the hole conducting layer contains p-type CNTs.

In the same or other embodiments, an electron conducting layer is positioned between the second electrode and the photoactive layer to facilitate electron transfer to the second electrode. In a preferred embodiment, the electron conducting layer contains n-type CNTs.

The carbon nanotube is preferably a single wall carbon nanotube (SWCNT). The SWCNT is preferably functionalized so as to be chemically reactive with the photosensitive nanoparticles of photosensitive nanoparticles that have been modified to contain functional groups that are reactive with the CNT/SWCNT or a moiety used to link the CNT/SWCNT photosensitive nanoparticle.

The photosensitive nanoparticles can be quantum dots, nanorods, nanobipods, nanotripods, nanomultipods or nanowires. Preferred photosensitive nanoparticles include CdSe, ZnSe, PbSe, InP, PbS, ZnS, Si, Ge, SiGe, CdTe, CdHgTe, or Group II-VI, II-IV or III-V materials. In some embodiments first and second nanoparticle that adsorb radiation from different portions of the solar spectrum are used in the photovoltaic device. The first and second nanoparticles can differ in composition, size or a combination of size and composition and absorb in different portions of the solar spectrum. The first and second can be nanoparticles contained or the same or different CNTs. For example two different photosensitive nanoparticles can each be associated with a single CNT. Alternatively, a first nanoparticle can be associated with a first CNT and a second nanoparticle with a second CNT. In either case a single photoactive layer can be made for such photoactive nanostructures.

The components used in the photovoltaic device are chosen so that appropriate band alignment exists between the photoactive nanostructure and the electrodes. When a conducting polymer is used in the photoactive layer, the HOMO and LUMO levels the conducting polymer are such that charge transfer is facilitated from the nanostructure to the conducting polymer and from conducting polymer to the electrode. Similarly, appropriate band alignment should exist between the photoactive layer and any electron or hole conducting layer used in the devices to facilitate charge extraction and charge transfer.

In another embodiment, a second photoactive layer is used that contains second photoactive nanostructures made of carbon nanotubes and nanoparticles that absorb radiation from different portions of the solar spectrum as compared to the nanoparticles of the first photoactive layer. The nanoparticles in the first and said second photoactive layer can differ in composition, size or a combination of size and composition.

In some embodiments, the hole conducting layer is a hole conducting polymer such as a p-type semiconducting polymer. Examples of p-type semiconducting polymers include P3HT, P3OT, MEH-PPV or PEDOT. In most embodiments, PVK is not used as a hole conducting polymer. In other embodiments, the hole conducting layer is a p-type semiconductor. Examples of p-type semiconductor include p-doped Si, p-doped Ge or p-doped SiGe. In the case of Si the p-type semiconductor can be p-doped amorphous silicon, p-doped microcrystalline silicon or p-doped nanocrystalline silicon. In some cases the hole conducting layer is made of two or more layers of p-type semiconductor. The p-type semiconductor layers can be a p-doped silicon layer, a p-doped germanium layer and/or a p-doped SiGe layer.

In a preferred embodiment the hole conducting layer contains CNTs, preferably SWCNTs. For example, SWCNTs can be combined with p-type P3HT and used as a hole conducting layer.

In some embodiments, the electron conducting layer is an electron conducting material such as aluminum quinolate (AlQ₃) and/or n-type SWCNTs made by doping SWCNTs with Cl₂, Br₂ or Cs.

### BRIEF DESCRIPTION OF THE DRAWING

FIG. 1 (Prior Art) depicts nanometer quantum dots of different size that absorb and emit radiation having different colors. Small dots absorb in the blue end of the spectrum while the large size dots absorb in the red end of the spectrum.

FIG. 2 (Prior Art) depicts quantum dots made from ZnSe, CdSe and PbSe that absorb/emit in UV visible and IR respectively.

FIG. 3 (Prior Art) depicts nanoparticles capped with solvents such as tri-n-octyl phosphine oxide (TOPO).

FIG. 4 depicts nanoparticles functionalized with an R group. The R group can be represented as Xₐ—Rₙ—Y_{b} where X and Y are reactive moieties such as a carboxylic acid (—COOH) group, a phosphoric acid (—H₂PO₄) group, a sulfonic acid (—HSO₃) group or an amine, a and b are 0 or 1 where one of a and b are 1, R is carbon, sulfur, nitrogen and/or oxygen and n=0-10 or 0-5.

FIG. 5 depicts Functionalized Carbon Nanotube 510 containing functional group R can be —COOH, —NH2, —PO₄, —HSO₃, Aminoethanethiol, etc.

FIG. 6 depicts a simple solar cell schematic where photosensitive nanostructures containing photosensitive nanoparticle sensitized carbon nanotubes (CNTs) are sandwiched between a transparent and a metal electrode.

FIG. 7 depicts a simple solar cell schematic where photoactive nanostructures containing photosensitive nanoparticle sensitized single wall carbon nanotubes (SWCNT) are dispersed in a conducting polymer layer sandwiched between a transparent and a metal electrode.

FIG. 8 depicts a photosensitive nanoparticle sensitized SWCNT solar cell design with one SWCNT interface layer 840.

FIG. 9 depicts a photosensitive nanoparticle sensitized SWCNT solar cell design with two SWCNT interface layers 930 and 950.

FIG. 10 depicts photoactive nanostructures containing photosensitive nanoparticle sensitized SWCNTs dispersed in a polymer matrix 1040 solar cell design with two SWCNT interface layers 1030 and 1050.

FIG. 11 depicts an alternative solar cell design where a photosensitive nanoparticle layer 1140 is sandwiched between two SWCNT interface layers 1130 and 1150. This layer may also include photoactive nanostructures made from CNTs and photosensitive nanoparticles.

FIG. 12 depicts another alternative solar cell design where photosensitive layer 1240 containing photosensitive nanoparticles dispersed in a polymer matrix is sandwiched between two SWCNT interface layers 1230 and 1250. This layer may also include photoactive nanostructures made from CNTs and photosensitive nanoparticles.

FIG. 13 depicts a photoactive device containing two photoactive layers. Layer 1330 contains photoactive nanostructures of CdSe-SWCNT while layer 1340 contains CdTe-SWCNT photoactive nanostructures.

FIG. 14 is similar to FIG. 13 except that the photoactive nanostructures of Layers 1430 and 1440 are dispersed in a polymer.

FIG. 15 depicts a solar cell design with a layer containing multiple types of photosensitive nanoparticles 1560, 1570 and 1580 attached to SWCNTs 1530.

FIG. 16 depicts a solar cell design with a layer containing multiple SWCNTs 1630 with each SWCNT attached to one type of photosensitive nanoparticle 1660, 1670 or 1680.

FIG. 17 depicts a SWCNT 1660, 1670 or 1680 solar cell design with multiple photoactive layers each containing photoactive nanostructures containing SWCNTs attached to a different type of photosensitive nanoparticle.

FIG. 18 depicts a solar cell design with a photoactive layer containing multiple types of photosensitive nanoparticles attached to each SWCNT sandwiched between two SWCNT layers.

### DETAILED DESCRIPTION OF THE INVENTION

An embodiment of the photovoltaic device disclosed herein is made from two electrodes and a photoactive layer comprising photoactive nanostructures. The photoactive nanostructures contain at least two components: (1) CNTs and/or SWCNTs and (2) photosensitive nanoparticles. The nanoparticles associate with the surface of the CNT by self assembly and cover at least 10% of the CNT's exterior surface although lighter particle densities, such as 50%, 70% or 90%, can be used. In preferred embodiments, the nanoparticles form a monolayer covering most of the CNT surface.

In a preferred embodiment, the nanoparticle is covalently attached to the CNT. This can be achieved by modifying the CNT and/or nanoparticles to contain a moiety/moieties that provide reactive sites for covalent linkage. In some instances (discussed below) a linker molecule is used to covalently attach the nanoparticle to the CNT.

As used herein, the term “nanoparticle” or “photosensitive nanoparticle” refers to photosensitive materials that generate electron hole pairs when exposed to solar radiation. Photosensitive nanoparticles are generally nanocrystals such as quantum dots, nanorods, nanobipods, nanotripods, nanomultipods, or nanowires.

Photosensitive nanoparticles can be made from compound semiconductors which include Group II-VI, II-IV and III-V materials. Some examples of photosensitive nanoparticles are CdSe, ZnSe, PbSe, InP, PbS, ZnS, CdTe Si, Ge, SiGe, CdTe, CdHgTe, and Group II-VI, II-IV and III-V materials. Photosensitive nanoparticles can be core type or core-shell type. In a core shell nanoparticle, the core and shell are made from different materials. Both core and shell can be made from compound semiconductors.

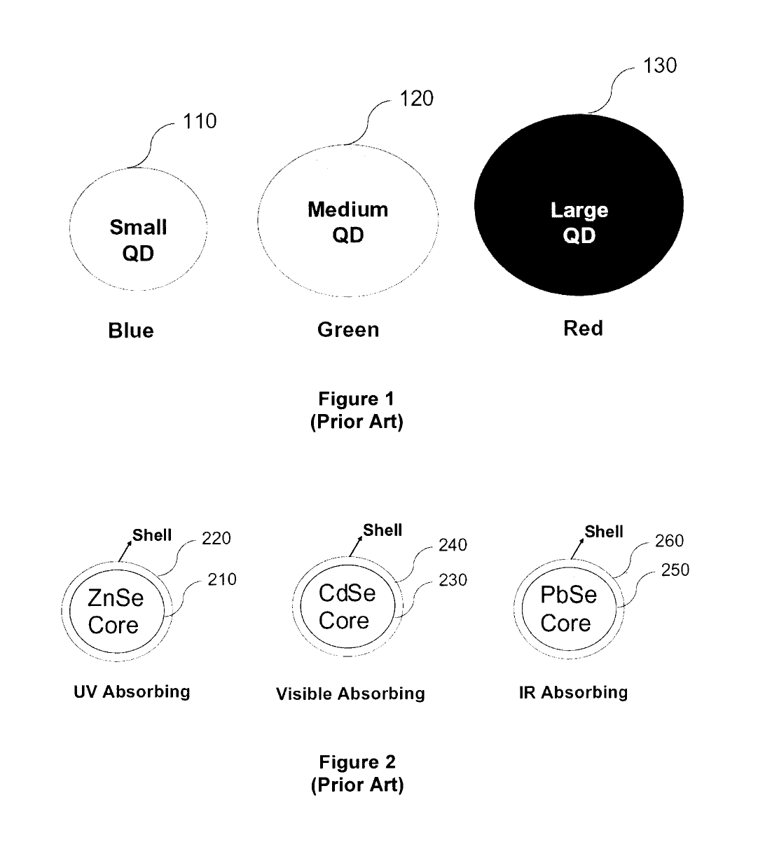

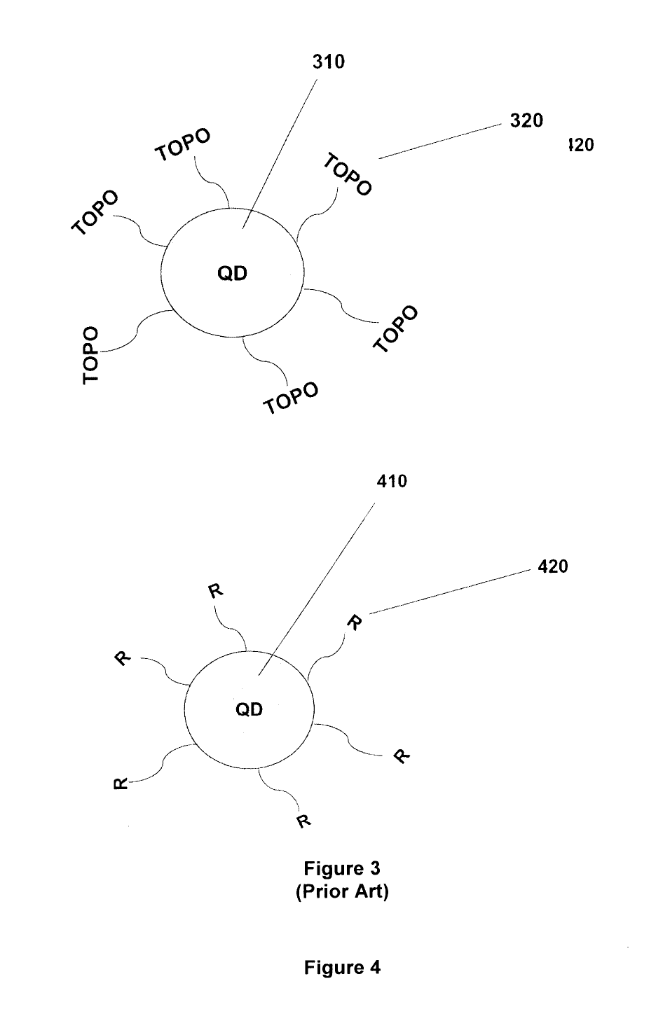

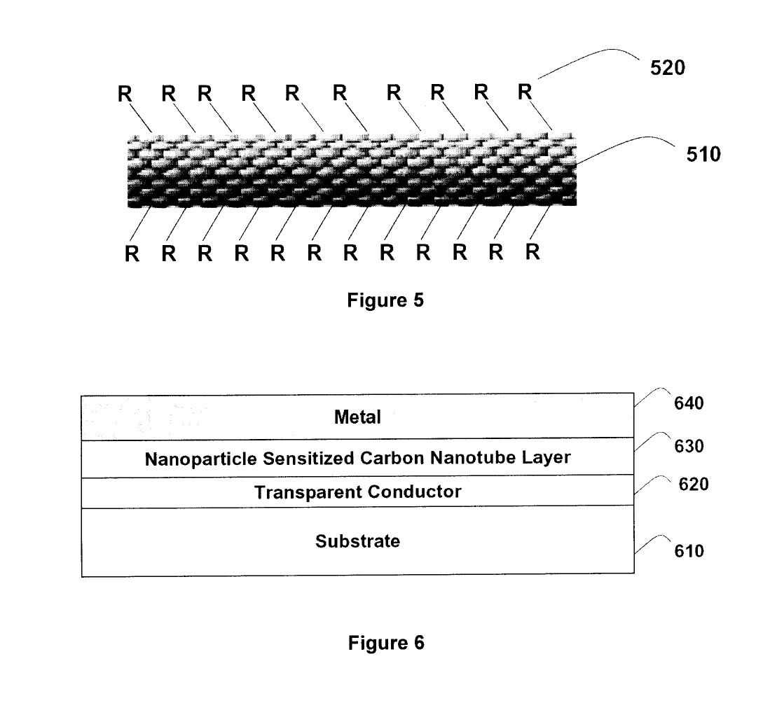

Quantum dots are a preferred nanoparticle. As in known in the art, quantum dots having the same composition but having different diameters absorb and emit radiation at different wave lengths. FIG. 1 depicts three quantum dots made of the same composition but having different diameters. The small quantum dot absorbs and emits in the blue portion of the spectrum; whereas, the medium and large quantum dots absorb and emit in the green and red portions of the visible spectrum, respectively. Alternatively, as shown in FIG. 2, the quantum dots can be essentially the same size but made from different materials. For example, a UV-absorbing quantum dot can be made from zinc selenide; whereas, visible and IR quantum dots can be made from cadmium selenide and lead selenide, respectively. Nanoparticles having different size and/or composition can be used either randomly or in layers to produce a broadband solar cell that absorbs in (1) the UV and visible, (2) the visible and IR, or (3) the UV, visible, and IR.

The photoactive nanoparticle can be modified to contain a linker Xₐ—Rₙ—Y_{b} where X and Y can be reactive moieties such as carboxylic acid groups, phosphonic acid groups, sulfonic acid groups, amine containing groups etc., a and b are independently 0 or 1 where at least one of a and b is 1, R is a carbon, nitrogen, sulfur and/or oxygen containing group such as —CH₂, —NH—, —S— and/or —O—, and n is 0-10. One reactive moiety can react with the nanoparticle while the other can react with the CNT. The linkers also passivate the nanoparticles and increase their stability, light absorption and photoluminescence. They can also improve the nanoparticle solubility or suspension in common organic solvents.

Functionalized nanoparticles are reacted with suitable reactive groups such as hydroxyl or others on the CNTs to deposit a monolayer of dense continuous nanoparticles by a molecular self assembly process. By adjusting the components of Xₐ—Rₙ—Y_{b}, the distance between the surface of the CNT and nanoparticle can be adjusted to minimize the effect of surface states in facilitating charge recombination. The distance between these surfaces is typically 10 Angstroms or less preferably 5 Angstroms or less. This distance is maintained so that electrons tunnel through this gap from the nanoparticles to the highly conducting CNTs. This facile electron transport helps in reducing charge recombination and results in efficient charge separation which leads to efficient solar energy conversion.

As used herein a “hole conducting layer” is a layer that preferentially conducts holes. Hole transporting layers can be made from (1) inorganic molecules including p-doped semiconducting materials such as p-type amorphous or microcrystalline silicon or germanium; (2) organic molecules such as metal-thalocyanines, aryl amines etc.; (3) conducting polymers such as polyethylenethioxythiophene (PEDOT), P3HT, P3OT and MEH-PPV; and (4) p-type CNTs or p-type SWCNTs.

As used herein an “electron conducting layer” is a layer that preferentially conducts electrons. Electron transporting layers can be made from aluminum quinolate (AlQ₃) and/or n-type CNTs or n-type SWCNTs.

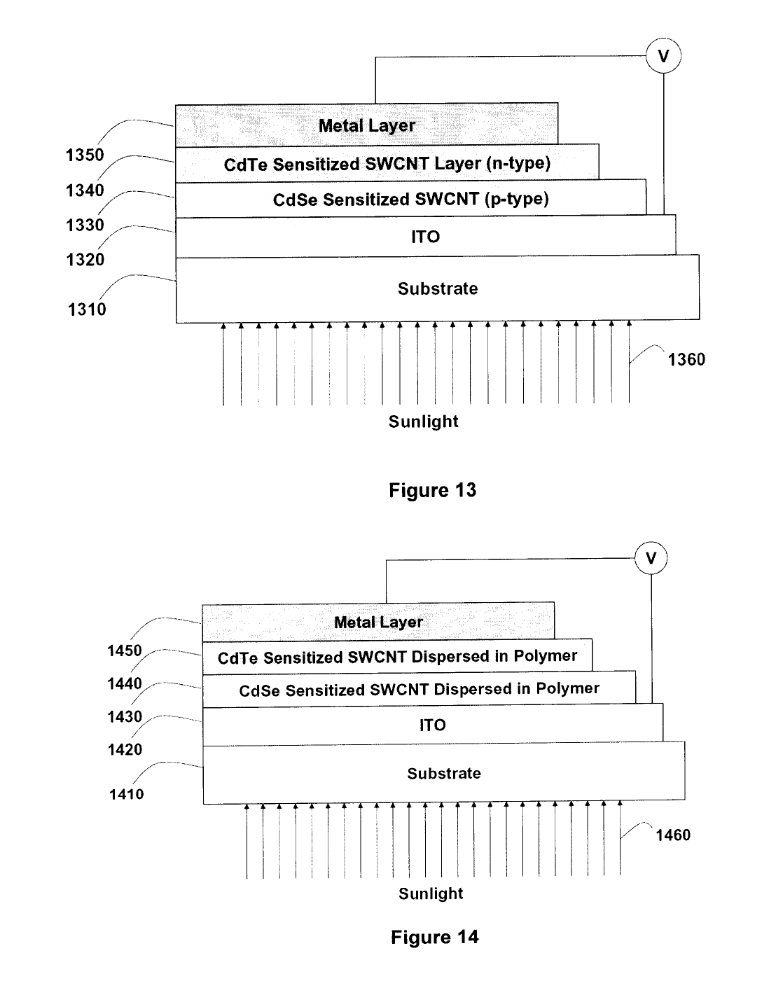

In some embodiments, the solar cell is a broadband solar cell that is capable of absorbing solar radiation at different wave lengths. Photosensitive nanoparticles generate electron-hole pairs when exposed to light of a specific wave length. The band gap of the photosensitive nanoparticles can be adjusted by varying the particle size or the composition of the nanoparticles. By combining a range of nanoparticle sizes and a range of the nanomaterials used to make the nanoparticles, broadband absorption over portions of or the entire solar spectrum can be achieved. Thus, in one embodiment, a mixture of photosensitive nanoparticles having a different size and/or composition can be layered on to the same or different CNTS to make broadband solar devices such as that set forth in FIGS. 13-18.

### EXAMPLE 1

FIG. 6 is a schematic of an embodiment of photosensitive nanoparticle sensitized carbon nanotube solar cell device made secondary to the invention. This solar cell can be built by depositing photoactive layer 630 containing photoactive nanostructures comprising photosensitive nanoparticle sensitized carbon nanotubes on a glass substrate layer 610 coated with transparent conductor layer 620 such as ITO followed by the deposition of cathode metal layer 640. The device (610 through 640) or subcomponents of the device (eg. 610, 620 and 630) are annealed at 200-400° C. for 6-12 hours.

Photosensitive nanoparticles can be made from Group IV, II-IV, II-VI, III-V materials. Examples of photosensitive nanoparticles include Si, Ge, CdSe, PbSe, ZnSe, CdTe, CdS, PbS. Nanoparticle sizes can be varied (for example: 2-10 nm) to obtain a range of bandgaps. These nanoparticles can be prepared by following the methods well known in the art. Nanoparticles can also be functionalized by following the methods well known in the art. Functional groups can include carboxylic (—COOH), amine (—NH₂), Phosphonate (—PO₄), Sulfonate (—HSO₃), Aminoethanethiol, etc. Carbon nanotubes can be prepared by following methods well known in the art. See, e.g., Landi et al., supra. They can also be purchased from Cheap Tubes Battleboro, Vt. or Aldrich. Carbon nanotubes are preferably single wall carbon nanotubes

Carbon nanotubes can be functionalized by following the methods well known in the art. See, e.g., Landi et al., supra. And Cho et al., Advanced Materials, 19, 232-236 (2007). Functionalized carbon nanotubes are soluble in common organic solvents such as chloroform. Functionalized carbon nanotubes can be reacted with functionalized photosensitive nanoparticles with appropriate functional groups dissolved in suitable solvent to prepare photosensitive nanoparticle sensitized carbon nanotubes. The density of the nanoparticle layer can be adjusted by varying the reaction conditions and by varying functional groups. Ideally a carbon nanotube densely decorated with photosensitive nanoparticles is desired. A layer of photosensitive nanoparticle sensitized carbon nanotubes can be deposited on ITO coated glass substrate by spin coating or other well known molecular self assembly techniques. This layer can be one monolayer or multiple monolayers. A solar cell built according this embodiment is expected to have high efficiency. In this device electron hole pairs are generated when sunlight is absorbed by the nanoparticles and the resulting electrons are rapidly transported by the carbon nanotubes to the cathode for collection. This rapid removal of electrons from the electron-hole pairs generated by the nanoparticles reduces the probability of electron-hole recombination commonly observed in nanoparticle based solar cell devices.

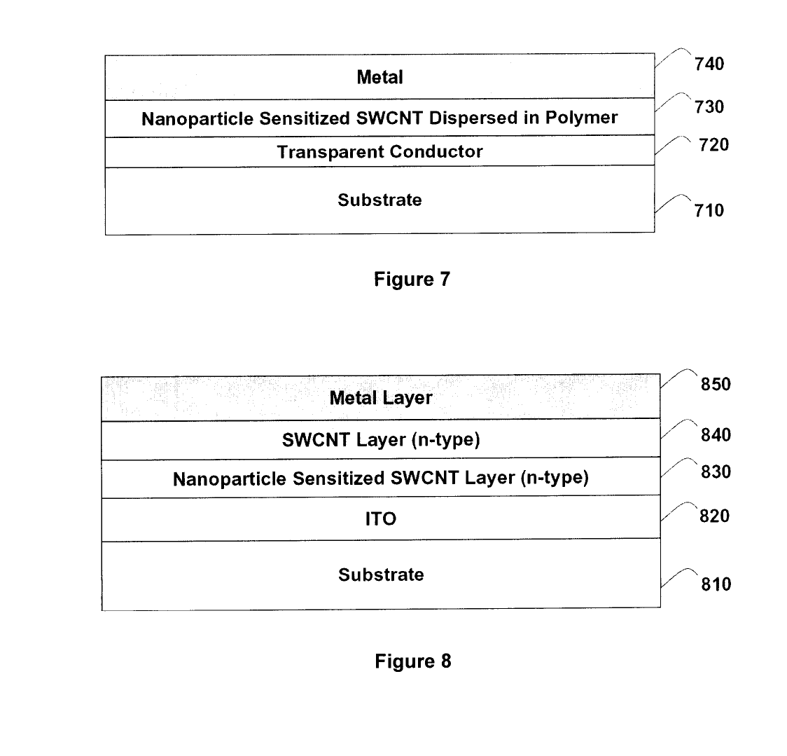

Another embodiment is shown in FIG. 7. The photoactive layer 730 contains photoactive nanostructures comprising photosensitive nanoparticle sensitized carbon nanotubes that are dispersed in a conducting polymers such PEDOT, P3HT etc. In another version of the embodiment shown in FIG. 7, the photoactive nanostructures are dispersed in organic semiconducting materials such as pentacene. The device or subcomponents of the device are annealed at 100-180° C. from about 10 minutes to about 6 hours. The lower temperature is chosen to limit degradation of the organic polymeric material.

EXAMPLE 3

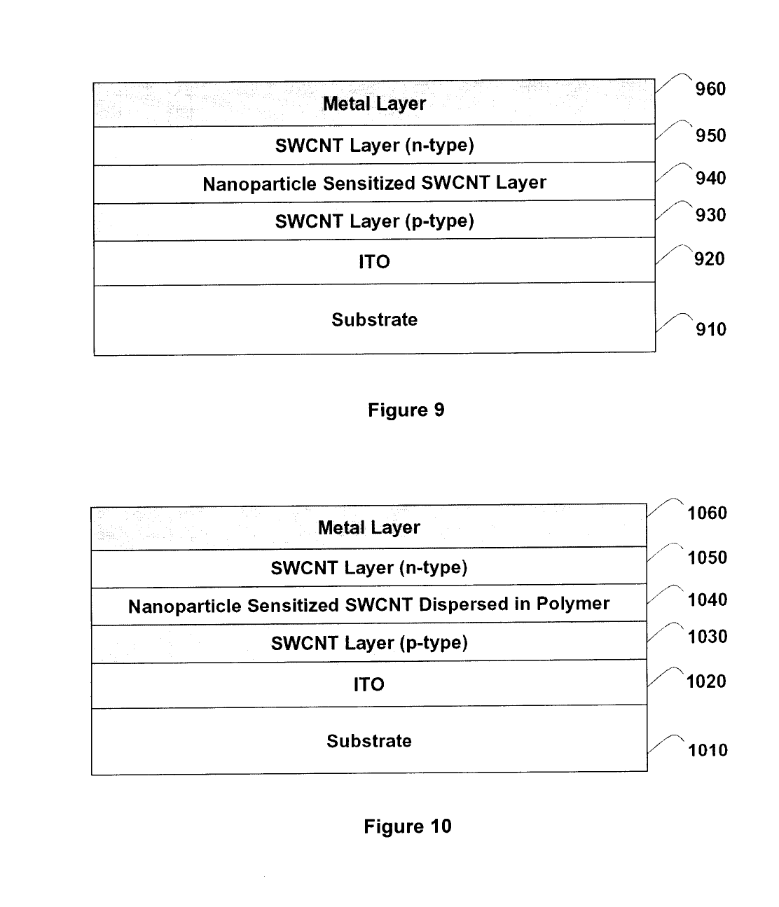

Another embodiment using photosensitive nanoparticle sensitized single wall carbon nanotubes (SWCNT) is shown in FIGS. 8 and 9 where nanoparticle sensitized SWCNT layer 830 or 940 is sandwiched between one SWCNT layer 840 (in FIG. 8) or two SWCNT layers 930 and 950 (in FIG. 9). Photosensitive nanoparticle sensitized SWCNT can be prepared using the methods described in Example 1. The solar cell device shown in FIG. 9 can be built by depositing SWCNT layer 930 on glass substrate 910 coated with transparent conductor such as ITO 920. the photoactive layer 940 is then deposited on top of SWCNT layer 930 followed by a second SWCNT layer 950 and a metal layer 960. The SWCNT used for layers 930 and 950 can be optionally functionalized to enable its dissolution in suitable organic solvents and to enhance its adhesion to the other layers. SWCNT deposition can be done by spin coating or other molecular self assembly methods well known in the art. The SWCNT layers used in this embodiment are expected to improve efficiency. SWCNT layer 930 can be p-type, and SWCNT layer 950 can be n-type. Such SWCNT layers act as electron conducting layers (n-type) or hole conducting layers (p-type).

In a version of this embodiment shown in FIG. 10, photosensitive nanoparticle sensitized carbon nanotubes can be dispersed in a conducting polymers such PEDOT, P3HT etc. to form photoactive layer 1040. In another version of this embodiment shown in FIG. 10, photosensitive nanoparticle sensitized carbon nanotubes can be dispersed in organic semiconducting materials such as pentacene to form layer 1040.

### EXAMPLE 4

In another embodiment, shown in FIG. 11, a photoactive layer 1140 is sandwiched between two SWCNT layers. The solar cell device shown in FIG. 11 can be built by depositing SWCNT layer 1130 on glass substrate 1110 coated with transparent conductor such as ITO 1120. Photosensitive nanoparticles are then deposited on top of SWCNT layer 1130 to form photoactive layer 1140 followed by a second SWCNT layer 1150 and metal layer 1160. The device or subcomponents of the device are annealed at 200-400° C. for 6 to 12 hours. This results in a photoactive layer 1140 that contains photosensitive nanoparticles alone or in combination with photoactive nanostructures comprising the photosensitive nanoparticles and the n- and/or p-type SWCNTs from layers 1150 and 1130, respectively. In some cases the photoactive layer 1140 contains photoactive nanostructures made from the photosensitive nanoparticles and the p- and/or n-type SWCNTs with little or no free nanoparticles present.

The SWCNT used for layers 1130 and 1150 can be optionally functionalized to enable its dissolution in suitable organic solvents and to enhance its adhesion to the other layers. SWCNT and nanoparticle deposition can be done by spin coating or other molecular self assembly methods well known in the art. The SWCNT layers used in this embodiment are expected to improve efficiency. SWCNT layer 1130 can be made from a p-type SWCNT. SWCNT layer 1150 can be made from an n-type SWCNT.

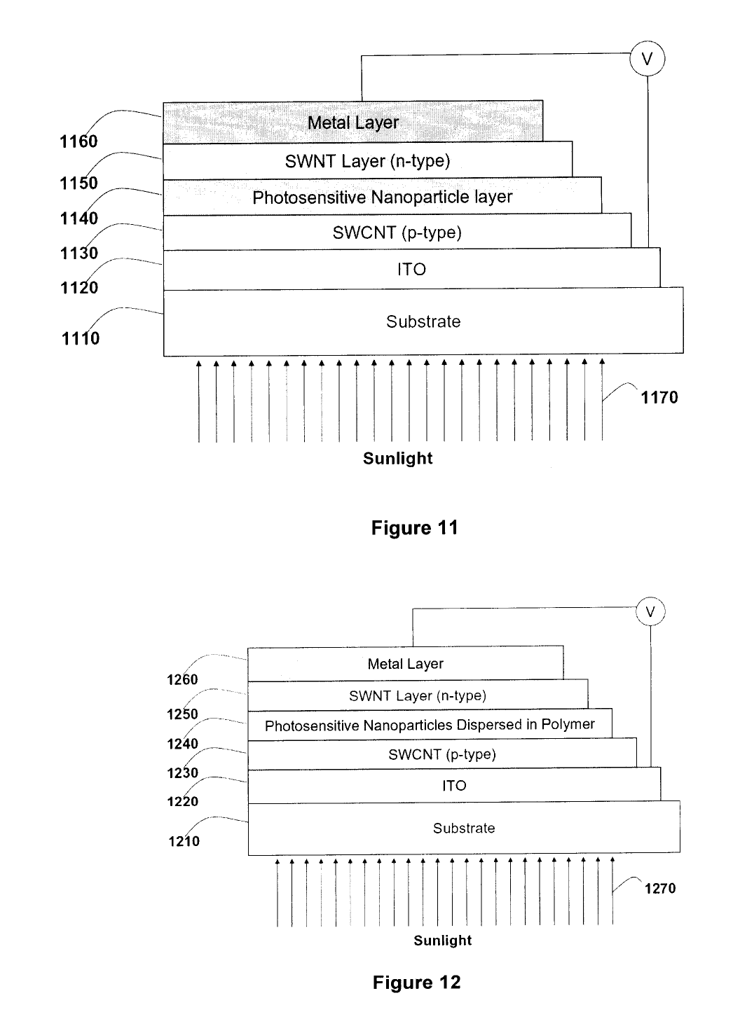

In a version of this embodiment shown in FIG. 12, the photoactive layer 1240 is made of photosensitive nanoparticles dispersed in a conducting polymer such as PEDOT or P3HT. In another version of this embodiment shown in FIG. 12, the photosensitive nanoparticles can be dispersed in organic semiconducting materials such as pentacene to form layer 1240. The device or subcomponents of the device are annealed at 100-180° C. for 10 minutes to 6 hours. This results in a photoactive layer 1240 that contains photosensitive nanoparticles alone or in combination with photoactive nanostructures comprising the photosensitive nanoparticles and the n- and/or p-type SWCNTs from layers 1250 and 1230, respectively. In some cases the photoactive layer 1240 contains photoactive nanostructures made from the photosensitive nanoparticles and the p- and/or n-type SWCNTs with little or no free nanoparticles present.

### EXAMPLE 5

In another embodiment shown in FIG. 13 two photoactive layers 1330 and 1340 are used. The solar cell device shown in FIG. 13 can be built by depositing a first photosensitive nanoparticle sensitized SWCNT such as CdSe-SWCNT layer 1330 on glass substrate 1310 that has been coated with a transparent conductor such as ITO 1320. A second photoactive layer 1340 is formed by depositing CdTe-SWCNT photoactive nanostructures followed by metal layer 1350. SWCNTs used for the layer 1330 can be p-type and the SWCNTs used for the layer 1340 can be n-type SWCNTs.

In a version of this embodiment shown in FIG. 14, the photoactive nanostructures are dispersed in a conducting polymers such PEDOT, P3HT etc. to form photoactive layers 1430 and 1440. In another version of the embodiment shown in FIG. 14, the photoactive nanostructures are dispersed in organic semiconducting materials such as pentacene to form layers 1430 and 1440.

### EXAMPLE 6

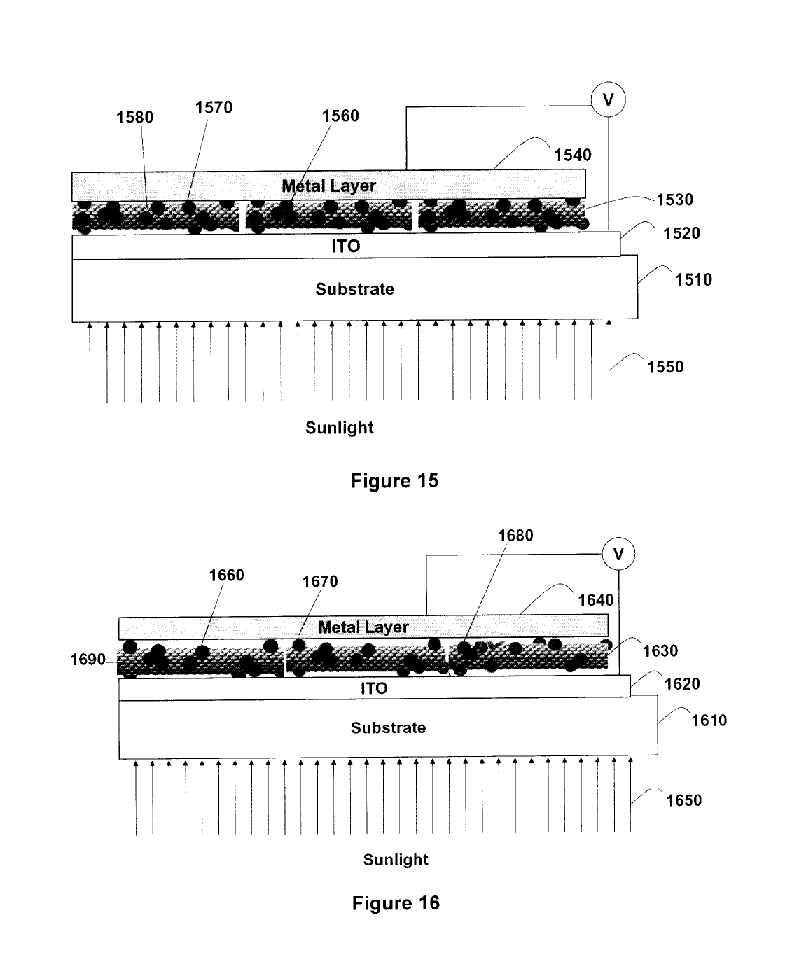

In another embodiment, shown in FIG. 15, various types of photosensitive nanoparticles 1560 of various sizes can be attached to SWCNTs to maximize photon harvesting efficiency.

Photosensitive nanoparticles can be made from Group IV, II-IV, II-VI, III-V materials. Photosensitive nanoparticles include Si, Ge, CdSe, PbSe, ZnSe, Cdje, CdS, PbS. One or more of these materials can be used to make the nanoparticles. Photosensitive nanoparticle sizes can range from 2-10 nm to obtain a range of bandgaps. Functionalized nanoparticles and functionalized SWCNT can be made using the methods described in Example 1.

For example, functionalized SWCNTs can be reacted with an appropriate mixture of functionalized photosensitive nanoparticles dissolved in suitable solvent to prepare photoactive nanostructures containing SWCNTs with multiple different photosensitive nanoparticles 1560, 1570 and 1580 attached as shown in FIG. 15. Material type, particle size and density can be adjusted by varying the composition of reaction mixture and reaction conditions. Ideally a carbon nanotube densely decorated with photosensitive nanoparticles covering a broad range of bandgaps is desired to harvest photons from the entire solar spectrum.

The solar cell shown in FIG. 15 can be prepared by depositing a photoactive layer of SWCNT 1530 attached with multiple types of photosensitive nanoparticles 1560, 1570 and 1580 on ITO 1520 coated glass substrate (1510) followed by a metal layer (1540).

In another version of this embodiment shown in FIG. 18, SWCNT interface layers 1830 and 1850 can be used to enhance the charge separation and collection efficiency and further enhance solar to electric conversion efficiency of these solar cells.

### EXAMPLE 7

In another embodiment shown in FIG. 16 a mixture of various types of photoactive nanostructures each containing different photosensitive nanoparticles are used in a photoactive layer to maximize photon harvesting efficiency. Functionalized SWCNTs are reacted with a functionalized photosensitive nanoparticle dissolved in suitable solvent to prepare SWCNT attached with the photosensitive nanoparticles 1660, 1670 or 1680. Different photosensitive nanoparticle sensitized SWCNTs can be mixed together to form photoactive layer 1690 as shown in FIG. 16. Material type, particle size and the ratio or the nanoparticles can be adjusted to obtain broadband absorption. The mixture of carbon nanotube densely decorated with photosensitive nanoparticles covering a broad range of bandgaps is used to harvest photons from a significant portion of the solar spectrum.

In another version of this embodiment shown in FIG. 18, SWCNT interface layers 1830 and 1850 can be used to enhance the charge separation and collection efficiency and further enhance solar to electric conversion efficiency of these solar cells.

### EXAMPLE 8

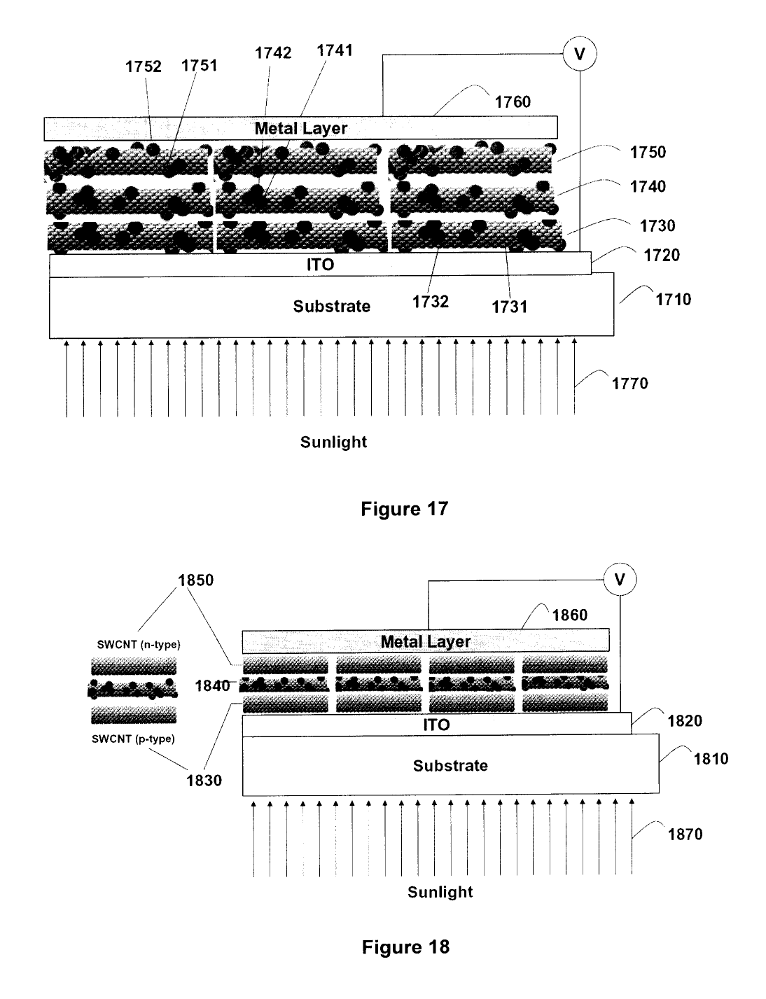

In another embodiment shown in FIG. 17 photoactive layers 1730, 1740 and 1750 are stacked on top of each other to maximize photon harvesting efficiency. Layer 1730 contains SWCNTs 1731 coated with nanoparticles 1732 while layer 1740 contains SWCNTs 1741 and nanoparticles 1742. Layer 1750 contains SWCNT 1751 and nanoparticles 1752.

The solar cell shown in FIG. 17 can be prepared by depositing photoactive layer 1730 on ITO 1720 coated glass substrate 1710. A second photoactive layer 1740 is then deposited on the first layer 1730 followed by a third layer 1750. The deposition of a metal layer 1760 completes the device.

In FIG. 17 three nanoparticle layers are shown as an example of stacked layer device. Additional layers can be used to increase efficiency.

In another version of this embodiment shown in FIG. 18, SWCNT interface layers 1830 and 1850 can be used to enhance the charge separation and collection efficiency and further enhance solar to electric conversion efficiency of these solar cells.

What is claimed is:

1. A photovoltaic device comprising:
a first electrode and a second electrode, at least one of which is transparent to solar radiation; and
a photoactive layer between said first and said second electrodes that is in electron conducting communication with said first electrode and in hole conducting communication with said second electrode, wherein said photoactive layer comprises a photoactive nanostructure comprising a carbon nanotube (CNT) and a photosensitive nanoparticle.

2. The photovoltaic device of claim 1 wherein said photosensitive nanoparticle is covalently attached to said CNT.

3. The photovoltaic devise of claim 1 wherein said photoactive layer further comprises a polymer in which said photoactive nanostructure is dispersed.

4. The photovoltaic devise of claim 1 wherein said carbon nanotube is a single walled carbon nanotube (SWCNT).

5. The photovoltaic devise of claim 1 wherein said photosensitive nanoparticle comprises a quantum dot, a nanorod, a nanobipod, a nanotripod, a nanomultipod or nanowire.

6. The photovoltaic devise of claim 5 wherein said photosensitive nanoparticle is a quantum dot.

7. The photovoltaic devise of claim 1 wherein said photosensitive nanoparticle comprises CdSe, ZnSe, PbSe, InP, PbS, ZnS, Si, Ge, SiGe, CdTe, CdHgTe, or Group II-VI, II-IV or III-V materials.

8. The photovoltaic devise of claim 1 wherein said photoactive layer comprises first and second photosensitive nanoparticles that absorb radiation from different portions of the solar spectrum.

9. The photovoltaic devise of claim 8 wherein said first and second nanoparticles differ in compositions.

10. The photovoltaic devise of claim 8 wherein said first and second nanoparticles have different size.

11. The photovoltaic devise of claim 8 wherein said first and said second nanoparticles differ in size and composition.

12. The photovoltaic devise of claim 8 where said first and second nanoparticles are attached to the same carbon nanotube.

13. The photovoltaic devise of claim 8 where said first and second nanoparticles are attached to different carbon nanotubes.

14. The photovoltaic devise of claim 1 further comprising a second photoactive layer comprising a nanostructure comprising a carbon nanotube and a different photosensitive nanoparticle, where said first and said second layers absorb radiation from different portions of the solar spectrum.

15. The photovoltaic devise of claim 14 wherein the nanoparticles of said first and said second photoactive layers differ in composition.

16. The photovoltaic devise of claim 14 wherein the nanoparticles of said first and said second photoactive layers have different sizes.

17. The photovoltaic device of claim 14 wherein the nanoparticles of said first and said second photosensitive layers differ in size and composition.

18. The photovoltaic devise of claim 1 or 14 further comprising a hole conducting layer between said second electrode and said photoactive layer(s).

19. The photovoltaic devise of claim 18 where said hole conducting layer comprises a hole conducting polymer.

20. The photovoltaic devise of claim 19 where said hole conducting polymer comprises P3HT, P3OT, MEH-PPV or PEDOT.

21. The photovoltaic devise of claim 18 where said hole conducting layer comprises a p-type CNT.

22. The photovoltaic devise of claim 18 wherein said hole conducting layer comprises a p-type semiconductor.

23. The photovoltaic devise of claim 22 wherein said p-type semiconductor is p-doped Si, p-doped Ge or p-doped SiGe.

24. The photovoltaic devise of claim 22 wherein said p-type semiconductor comprises p-doped amorphous silicon, p-doped microcrystalline silicon or p-doped nanocrystalline silicon.

25. The photovoltaic devise of claim 1 or 14 further comprising an electron conducting layer between said first electrode and said photoactive layer(s).

26. The photovoltaic devise of claim 25 where said electron conducting layer comprises an electron conducting molecule.

27. The photovoltaic devise of claim 26 where said electron conducting molecule comprises aluminum quinolate.

28. The photovoltaic devise of claim 26 where said electron conducting layer comprises an n-type CNT.

29. The photovoltaic devise of claim 26 wherein said hole conducting layer comprises an n-type semiconductor.

30. The photovoltaic devise of claim 29 wherein said n-type semiconductor is amorphous, microcrystalline, or nanocrystalline n-doped silicon.

31. A photovoltaic devise comprising:
a first electrode and a second electrode, where at least one of said first and second electrodes is transparent to solar radiation and where at least one of said first and second electrodes comprises a carbon nanotube (CNT); and
a photoactive layer between said first and said second electrodes that is in electron conducting communication with said first electrode and in hole conducting communication with said second electrode, wherein said photoactive layer comprises a photosensitive nanoparticle.

32. The photovoltaic device of claim 31 where said photoactive layer further comprises a photoactive nanostructure comprising a CNT and a photosensitive nanoparticle.
